(19) United States
(12) Patent Application Publication
(10) Pub. No.: US 2019/0139802 A1
(43) Pub. Date: May 9, 2019

(54) FRONT OPENING UNIFIED POD LOADING AND AIR FILLING SYSTEM

(71) Applicant: FOXSEMICON INTEGRATED TECHNOLOGY, INC., Miao-Li Hsien (TW)

(72) Inventors: YI-CHUN CHIU, New Taipei (TW); CHUN-KAI HUANG, New Taipei (TW); CHIH-CHENG LU, Miaoli Hsien (TW); CHUN-CHUNG CHEN, Miaoli Hsien (TW); CHEN-TSU FU, New Taipei (TW); SHENG-FU TSAI, New Taipei (TW)

(21) Appl. No.: 15/835,411

(22) Filed: Dec. 7, 2017

(30) Foreign Application Priority Data
Nov. 7, 2017 (TW) 106138521

(51) Int. Cl. H01L 21/673

(52) U.S. Cl. CPC H01L 21/67389

(57) ABSTRACT

A front opening unified pod (FOUP) loading and air filling system comprises a FOUP loading device and an air filling device. The FOUP loading device is configured to load and unload a FOUP, and comprises a substrate and a controller. The substrate comprises a frame, a bearing platform installed on the frame, and a cavity under the bearing platform. The bearing platform is configured to support the FOUP. The controller and the air filling device are accommodated in the cavity. The air filling device is connected to the FOUP.

### FIELD

The subject matter herein generally relates to a front opening unified pod (FOUP) loading and air filling system.

### BACKGROUND

FOUPs are plastic enclosures designed to securely and safely hold silicon wafers in a controlled environment, and to allow the silicon wafers to be transferred between machines for processing.

With shorter manufacturing processes, the queuing time between two successive procedures also becomes shorter. Thus, silicon wafers waiting for a time period longer than the queuing time may lose efficacy. Thus, it may be desirable to increase the queuing time between two successive procedures. To maintain quality of the silicon wafers, a FOUP loading device is needed to load and unload the FOUPs and to purify air in the FOUP by an air filling device to remove moisture and oxygen, thereby avoiding contamination and/or damage to the silicon wafers. The FOUP loading device and the air filling device form a FOUP loading and air filling system together. However, the FOUP loading and air filling system occupies a large space.

### BRIEF DESCRIPTION OF THE DRAWINGS

Implementations of the present disclosure will now be described, by way of example only, with reference to the attached figures.

FIG. 1 is a diagram of an exemplary embodiment of a front opening unified pod (FOUP) loading and air filling system.

FIG. 2 is a diagrammatic view showing a housing of the FOUP loading and air filling system of FIG. 1 detachably installed on the frame of the FOUP loading and air filling system of FIG. 1.

FIG. 3 is a block diagram of an exemplary embodiment of an air filling device of the FOUP loading and air filling system of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “comprising” when utilized, means “including, but not necessarily limited to”; it specifically indicates open-ended inclusion or membership in the so-described combination, group, series, and the like.

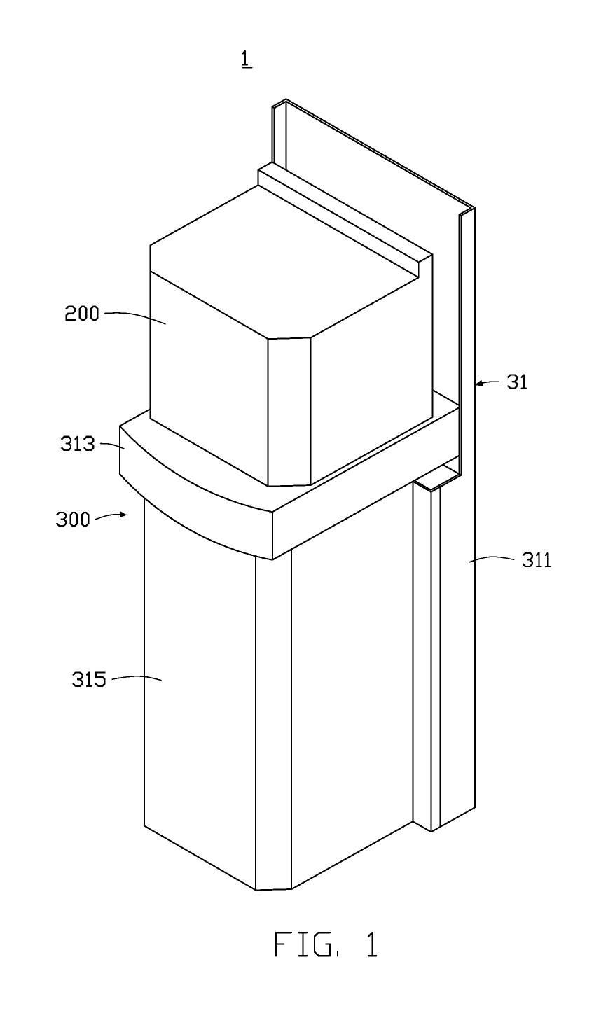

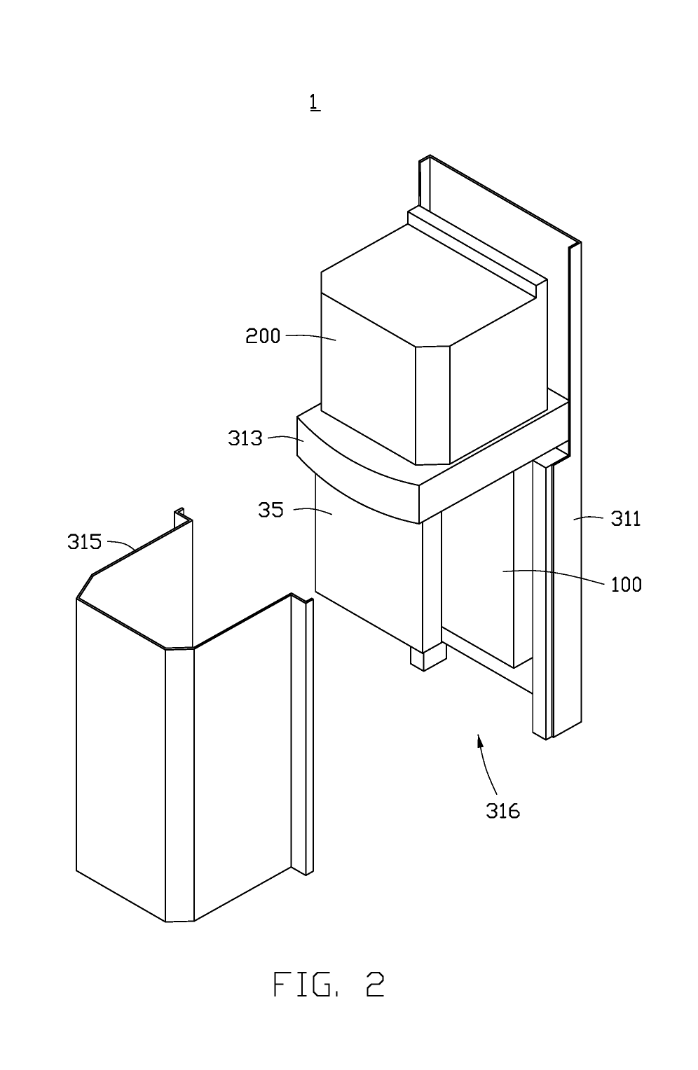

FIGS. 1 and 2 illustrates an exemplary embodiment of a FOUP loading and air filling system 1 comprising a FOUP loading device 300 and an air filling device 100. The air filling device 100 supplies air to a FOUP 200 on the FOUP loading device 300 to protect wafers in the FOUP 200.

The FOUP loading device 300 comprises a substrate 31 and a controller 35.

The substrate 31 comprises a frame 311, a bearing platform 313, and a cavity 316. The bearing platform 313 protrudes from the frame 311 along a direction perpendicular to the frame 311, to support the FOUP 200. The cavity 316 is under the bearing platform 313, and is surrounded by the frame 311, the bearing platform 313, and a housing 315. The controller 35 is accommodated in the cavity 316 to control the loading and unloading of the FOUP 200. The housing 315 is installed on the frame 311 detachably. Thereby, it is easier to assemble and maintain the FOUP loading and air filling system 1.

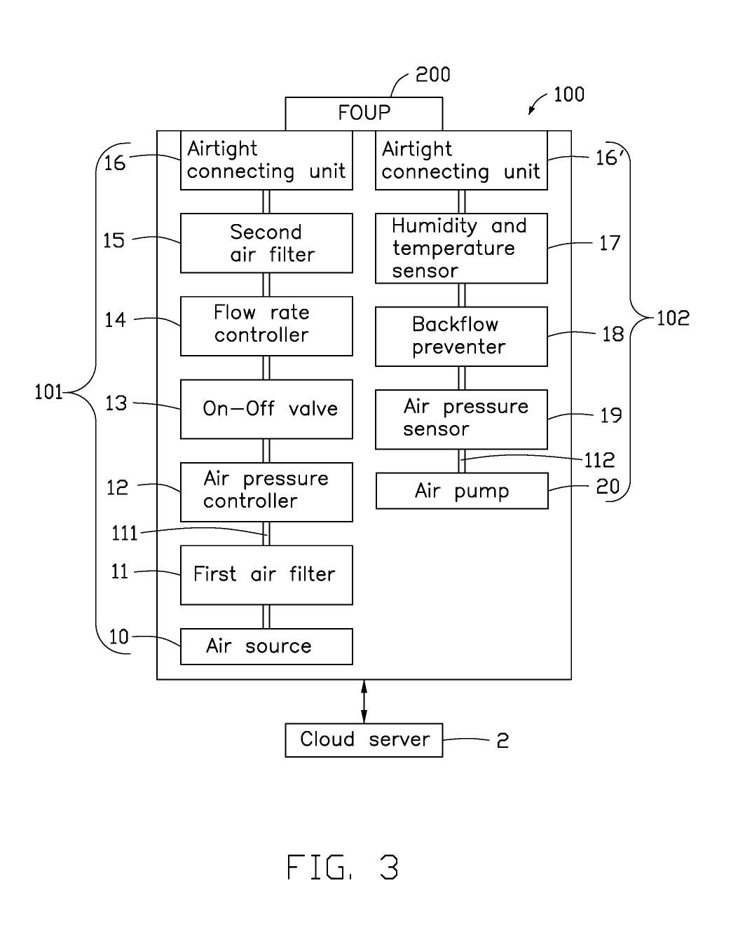

In at least one exemplary embodiment, the controller 35 can communicate with a cloud server 2 (shown in FIG. 3) in a wired or a wireless manner. The cloud server 2 sends a control signal to the controller 35, to inform the controller 35 to begin to load or to begin to unload the FOUP 200.

The air filling device 100 is accommodated in the cavity 316. In at least one exemplary embodiment, the air filling device 100 and the controller 35 are arranged side by side in the cavity 316. The air filling device 100 is located between the controller 35 and the frame 311. The air filling device 100 is fixed on the frame 311, and the controller 35 is fixed on a surface of the bearing platform 313 facing the cavity 316. In another exemplary embodiment, an arrangement of the air filling device 100 and the controller 35 can be varied according to specific needs.

With the above configuration, the air filling device 100 and the controller 35 are accommodated in the cavity 316, so that the FOUP loading and air filling system 1 is compact, thereby saving space.

Referring to FIG. 3, the air filling device 100 comprises an air supply assembly 101 and an air discharging assembly 102. When the air supply assembly 101 receives a trigger signal, the air supply assembly 101 supplies purified air to the FOUP 200, the purified air meets requirements of humidity and air pressure. The air discharging assembly 102 discharges air from the FOUP 200 when the air supply assembly 101 begins to supply the purified air to the FOUP 200, and detects a humidity and a temperature of the discharged air. The detected humidity and the detected temperature correspond to a relative humidity of the discharged air.

In at least one exemplary embodiment, the air purifying device 100 can communicate with the cloud server 2 in a wired or a wireless manner. The cloud server 2 sends the trigger signal to the air supply assembly 101 and the air discharging assembly 102, to inform the air supply assembly 101 to begin to supply purified air to the FOUP 200, and the air discharging assembly 102 to begin to discharge air from the FOUP 200. The air purifying device 100 further sends the detected humidity and the detected temperature of the discharged air to the cloud server 2. Thus, the cloud server 2 can calculate the relative humidity of the discharged air according to the detected humidity and the detected temperature, and compare the calculated relative humidity with a preset relative humidity. When the calculated relative humidity is equal to the preset relative humidity, the cloud server 2 sends a stop signal to the air supply assembly 101 and the air discharging assembly 102. The stop signal causes the air supply assembly 101 to stop supplying the purified air to the FOUP 200, and the air discharging assembly 102 to stop discharging air from the FOUP 200. That is, the air purifying device 100 stops working.

In other exemplary embodiment, the air supply assembly 101 can communicate with the air discharging assembly 102 in a wired or a wireless manner. The air discharging assembly 102 calculates the relative humidity of the discharged air and compares the calculated relative humidity with the preset relative humidity. When the calculated relative humidity is equal to the preset relative humidity, the air discharging assembly 102 stops discharging air from the FOUP 200. The air discharging assembly 102 further sends a stop signal to the air supply assembly 101, thereby causing the air supply assembly 101 to stop supplying the purified air to the FOUP 200.

The purified air can be, but is not limited to, compressed dry air (CDA), nitrogen (N₂), and combinations.

The air supply assembly 101 comprises an air source 10. The air supply assembly 101 can process air from the air source 10 to obtain the purified air and supply the purified air to the FOUP 200. In at least one exemplary embodiment, the air supply assembly 101 further comprises a first air filter 11, an air pressure controller 12, an On-Off valve 13, a flow rate controller 14, a second air filter 15, an airtight connecting unit 16, and an air supply tube 111. The air supply tube 111 connects the first air filter 11, the air pressure controller 12, the On-Off valve 13, the flow rate controller 14, the second air filter 15, and the airtight connecting unit 16. The air supply assembly 101 is connected to the air source 10 through the first air filter 11, and further connected to the FOUP 200 through the airtight connecting unit 16. The air pressure controller 12, the On-Off valve 13, the flow rate controller 14, and the second air filter 15 are arranged between the first air filter 11 and the airtight connecting unit 16 in that order. In other exemplary embodiments, the order of connections between the air pressure controller 12, the On-Off valve 13, the flow rate controller 14, and the second air filter 15 may vary according to need.

The first air filter 11 filters the air from the air source 10 to remove fine particles (for example, dust).

The air pressure controller 12 senses an air pressure of the air from the first air filter 11, and compares the sensed air pressure to a preset air pressure range. If the sensed air pressure is outside the preset air pressure range, the air pressure controller 12 adjusts the air pressure of the air until the sensed air pressure falls within the preset air pressure range. In at least one exemplary embodiment, the air pressure controller 12 comprises an air pressure sensor and an air pressure valve. The preset air pressure range is about −1 kpa to about −6 kpa.

The On-Off valve 13 can be switched between an On-state and an Off-state. When the On-Off valve 13 is in the On-state, the On-Off valve 13 can allow the air from the air pressure controller 12 to pass through. When the On-Off valve 13 is in the Off-state, the On-Off valve 13 prevents the air from passing through. That is, the On-Off valve 13 can control the air supply assembly 101 to stop supplying air to the FOUP 200.

The flow rate controller 14 senses a flow rate of the air from the On-Off valve 13, and compares the sensed flow rate with a preset flow rate range. When the sensed flow rate is outside the preset flow rate range, the flow rate controller 14 adjusts the flow rate of the air until the sensed flow rate falls within the preset flow rate range. The preset flow rate range can be less than 100 L/min.

The second air filter 15 further filters the air from the flow rate controller 14, thereby removing fine particles in the air generated by the first air filter 11, the air pressure controller 12, the On-Off valve 13, and the flow rate controller 14, to obtain the purified air.

In at least one exemplary embodiment, the air discharging assembly 102 comprises an airtight connecting unit 16′, a humidity and temperature sensor 17, a backflow preventer 18, an air pressure sensor 19, an air pump 20, and an air discharging tube 112 connecting the airtight connecting unit 16′, the humidity and temperature sensor 17, the backflow preventer 18, the air pressure sensor 19, and the air pump 20. The air discharging tube 112 connects the airtight connecting unit 16′, the humidity and temperature sensor 17, the backflow preventer 18, the air pressure sensor 19, and the air pump 20

The air pump 20 generates negative air pressure which pulls the air in the FOUP 200 towards the air pump 20. In at least one exemplary embodiment, the air pump 20 is a vacuum air pump. The airtight connecting unit 16′, the humidity and temperature sensor 17, the backflow preventer 18, and the air pressure sensor 19 are arranged between the FOUP 200 and the air pump 20 in that order. In other exemplary embodiments, the order of connection of the airtight connecting unit 16′, the humidity and temperature sensor 17, the backflow preventer 18, and the air pressure sensor 19 may vary according to need.

The airtight connecting unit 16′ connects the humidity and temperature sensor 17 to the FOUP 200 in an airtight manner, thereby avoiding any air leakage when the discharged air enters the humidity and temperature sensor 17. In at least one exemplary embodiment, the structure of the airtight connecting unit 16′ is substantially similar to that of the airtight connecting unit 16.

The humidity and temperature sensor 17 detects the humidity and the temperature of the discharged air. In at least one exemplary embodiment, the humidity and temperature sensor 17 comprises a temperature-sensitive resistor and a humidity-sensitive resistor. When the relative humidity of the discharged air is equal to the preset relative humidity, the air source 10 is shut down, and the air supply assembly 101 stops supplying the purified air to the FOUP 200.

The air pressure sensor 19 senses an air pressure of the discharged air.

The backflow preventer 18 prevents backflow of the discharged air when the sensed air pressure is greater than a preset air pressure (for example, when the negative air pressure changes to positive air pressure). That is, the backflow preventer 18 can prevent air from the ambient environment from flowing back to the FOUP 200. In at least one exemplary embodiment, the backflow preventer 18 is a check valve.

The air purifying device 100 and the controller 35 do not interfere with each other.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A front opening unified pod (FOUP) loading and air filling system comprising:
a FOUP loading device configured to load and unload a FOUP, the FOUP loading device comprising:
a substrate comprising a frame, a bearing platform installed on the frame, and a cavity under the bearing platform; and
a controller; a plurality of rotating shafts parallel to one another and arranged in arrays;
an air filling device connected to the FOUP;
wherein the bearing platform is configured to support the FOUP, the controller and the air filling device are accommodated in the cavity.

2. The FOUP loading and air filling system of the claim 1, the FOUP loading and air filling system further comprises a housing installed on the frame, the cavity is surrounded by the frame, the bearing platform, and a housing.

3. The FOUP loading and air filling system of the claim 2, wherein the housing is installed on the frame detachably.

4. The FOUP loading and air filling system of the claim 1, wherein the air filling device and the controller are arranged side by side in the cavity.

5. The FOUP loading and air filling system of the claim 4, wherein the air filling device is located between the controller and the frame.

6. The FOUP loading and air filling system of the claim 5, wherein the air filling device is fixed on the frame, and the controller is fixed on a surface of the bearing platform facing to the cavity.

7. The FOUP loading and air filling system of the claim 1, wherein the controller and the air filling device can communicate with a cloud server, the controller is informed to begin to load or to begin to unload the FOUP by a control signal from the cloud server, the air purifying device is informed to begin or stop to supply purified air to the FOUP and discharge air from the FOUP by a trigger signal from the cloud server.

8. The FOUP loading and air filling system of the claim 1, wherein the air filling device comprises an air supply assembly and an air discharging assembly, the air supply assembly is connected to the FOUP to supply purified air to the FOUP, the air discharging assembly is connected to the FOUP to discharge air from the FOUP.

9. The FOUP loading and air filling system of the claim 8, wherein air discharging assembly detects a humidity and a temperature of the discharged air, the detected humidity and the detected temperature corresponding to a relative humidity of the discharged air.

10. The FOUP loading and air filling system of the claim 9, wherein when the relative humidity is equal to a preset relative humidity, the air supply assembly stops supplying the purified air to the FOUP and the air discharging assembly stops discharging air from the FOUP.
